(19) United States
(12) Patent Application Publication
(10) Pub. No.: US 2011/0298342 A1
(43) Pub. Date: Dec. 8, 2011

(54) FRONT REMOVABLE EXPANSION CARD MODULE STRCUTURE

(76) Inventor: Shin-Jau LI, New Taipei City (TW)

(21) Appl. No.: 13/151,941

(22) Filed: Jun. 2, 2011

(30) Foreign Application Priority Data
Jun. 2, 2010 (TW) 099210457

(51) Int. Cl. H05K 5/02

(52) U.S. Cl. 312/223.2

(57) ABSTRACT

The present invention discloses an improved front removable expansion card module structure applied to an electronic device and comprising: a casing, a cover panel disposed at the top of the casing, an opening formed on a lateral side of the casing, an adapter frame contained in the opening and having a second adaptor interface inserted into a first slot of the first adaptor interface erected in the casing; and one or more second slots formed on the second adaptor interface and parallel to the opening, such that users simply need to pull the adapter frame from the opening to separate the second adaptor interface from the first slot, and then draw the adapter frame to the outside completely for maintenance and repair, without the need of removing the cover panel from the casing, so as to provide a very convenient application.

### BACKGROUND OF THE INVENTION

1. Field of the Invention

The present invention relates to an improved front removable expansion card module structure, and more particularly to an expansion card module structure applied in an electronic device, such that the electronic device can be maintained or repaired without the need of removing a front panel from a casing.

2. Brief Description of the Related Art

Compared with the well-known personal computers and servers, most people are undoubtedly unfamiliar with industrial computers. In fact, industrial computers generally refer to computers other than personal computers and servers, including automatic transfer machines, POS systems, ATM systems, stock and security exchange operating systems, hotels, airports, inquiry systems, hospital registration systems, and medical treatment systems, hotel reservation systems, restaurant reservation systems, automatic car park payment machines, industrial automation systems, workstation operating systems, communication network control systems, and KIOSK real-time information stations that are commonly used in our daily life. In the range of a general definition, the industrial computer refers computers in the vertical industry, and the scope of applicability covers factory automation, security surveillance, and medical treatment system. Unlike the general PC, the industrial computer is applicable to the a more complicated environment, and some industrial computers are operated at high temperature for a long time or in factory with vibrations, and some industrial computers have strict requirements on heat dissipation, stability and vibration resistance. In addition, the scope of applicability of the industrial computer is very broad, and manufacturers have to custom make the industrial computers according to the customer specifications, and the quantity of the order is relatively small, or even the quantity of several tens for one model, and the diversified customer requirements creates the feature of the “small-quality and large-variety” industrial computer industry.

According to the function and features of a product, the industrial computer can be mainly divided into a single board computer (SBC), an industrial chassis, a panel PC, an industrial control card, and a workstation, and a vast majority of industrial computers still adopts the PC-based architecture, and a specification different from the PC specifications. For the core of the industrial computer—the single board computer, the single board computer plays a role similar to the motherboard of a personal computer and includes core components such as a processor, a memory, and a system chipset, but with a much smaller size. A long card of a standard specification is not much longer than the GeForce 4 Ti4600 display card, not even mentioning the half-height short card or an embedded motherboard with the size of a 5.25-inch hard disk.

To facilitate maintenance and repair, most single board computers are designed with the interface card type and adopt ISA/PCI interfaces installed on a passive backplane in a chassis. Since the production lines of an automated factory usually have many computers for the control, the loss incurred by system down can be minimized if an individual board can be replaced when one of the computers breaks down.

The structure of a panel PC generally comprises a casing, and peripherals such as a motherboard and disk drives are installed in the casing, and a panel is installed at the front side of the casing, and a display screen is installed on the panel. When such computer is repaired or expanded, it is necessary to remove the casing first, and then the display screen is removed from the casing, before the devices in the casing can be replaced, or expanded. Such application is very inconvenient.

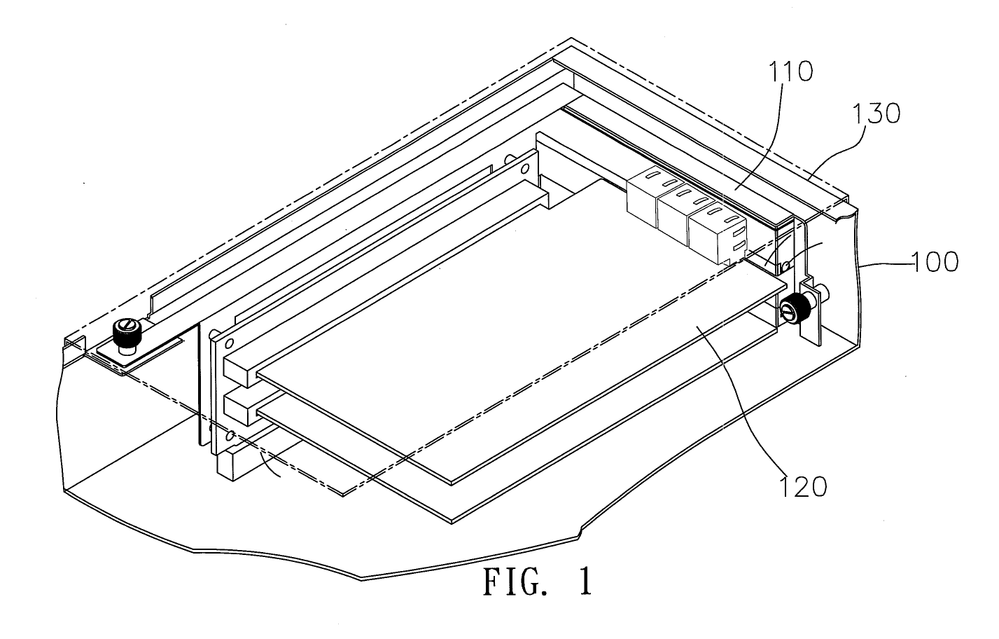

With reference to FIG. 1 for an industrial computer, the industrial computer comprises a casing 100, a frame mounted in the casing 100 and secured in casing 100, and a plurality of parallel expansion cards 120 inserted into the frame 110. in addition, the casing 100 further includes a cover panel 130, which is generally lifted open before the computer can be maintained or repaired, and the frame 110 must be loosened for the maintenance and repair. Obviously, such application is very inconvenient.

### SUMMARY OF THE INVENTION

In view of the foregoing drawbacks of the prior art, the inventor of the present invention based on years of experience in the related industry to conduct extensive researches and experiments, and finally developed an improved front removable expansion card module structure in accordance with the present invention to overcome the drawbacks of the present invention.

Therefore, it is a primary objective of the present invention to provide an comprising: a casing, a cover panel disposed at the top of the casing, an opening formed on a lateral side of the casing, an adapter frame contained in the opening and having a second adaptor interface inserted into a first slot of the first adaptor interface erected in the casing; and one or more second slots formed on the second adaptor interface and parallel to the opening, such that users simply need to pull the adapter frame from the opening to separate the second adaptor interface from the first slot, and then draw the adapter frame to the outside completely for maintenance and repair, without the need of removing the cover panel from the casing, so as to provide a very convenient application.

The technical contents of the present invention will become apparent by the detailed description of the preferred embodiments together with the illustration of related drawings as follows:

### BRIEF DESCRIPTION OF THE INVENTION

FIG. 1 is a schematic view of a conventional expansion card module;

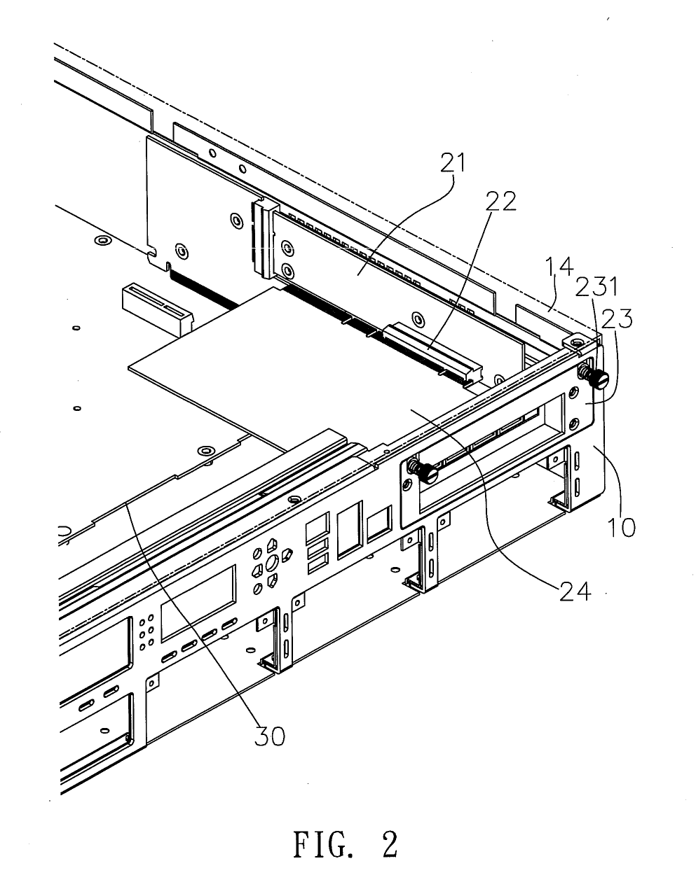

FIG. 2 is a schematic view of a preferred embodiment of the present invention;

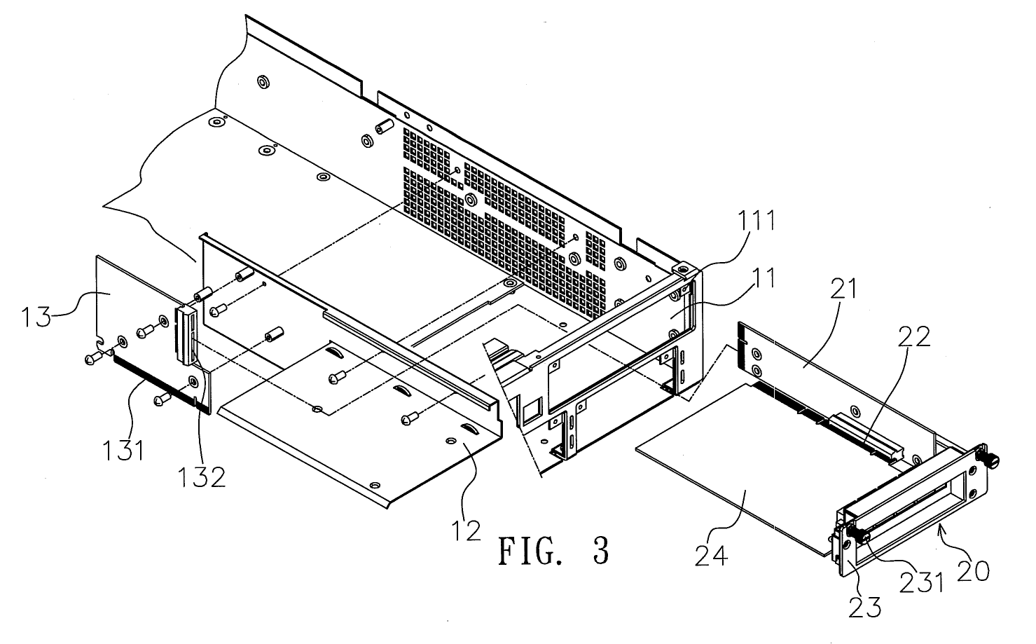

FIG. 3 is an exploded view of a preferred embodiment of the present invention;

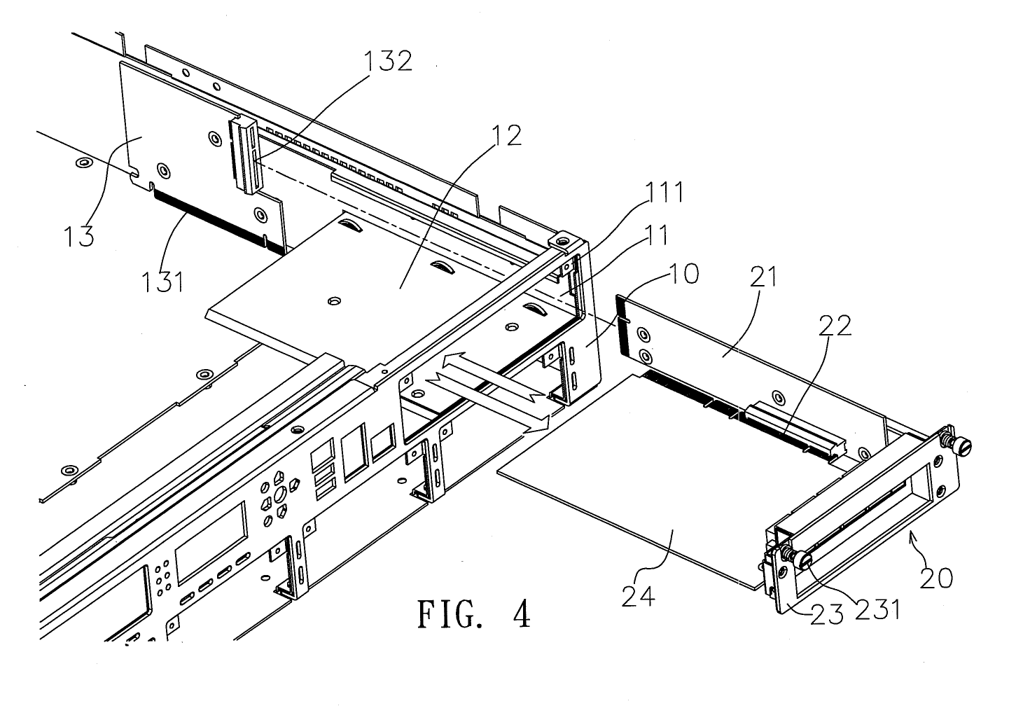

FIG. 4 is a schematic view of an operation in accordance with a preferred embodiment of the present invention; and

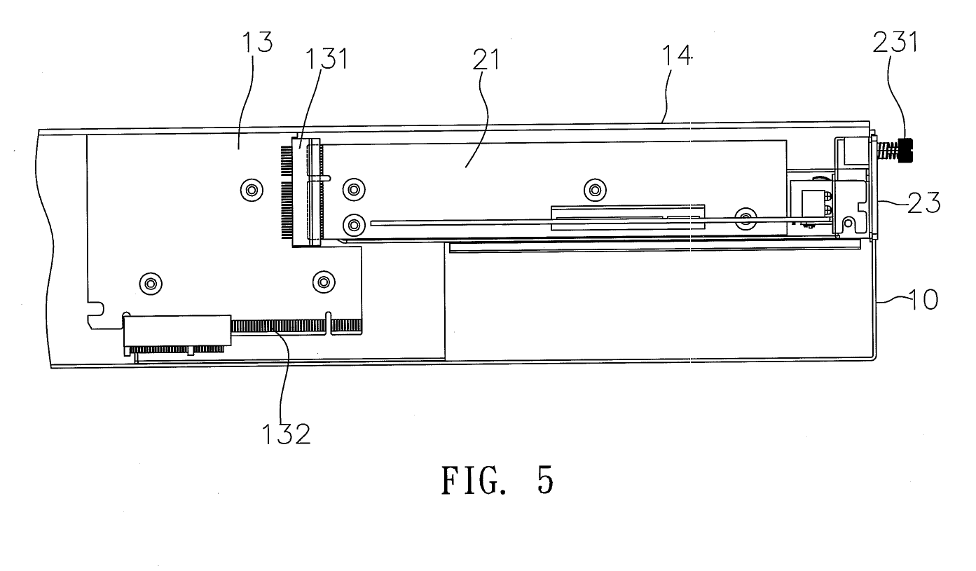

FIG. 5 is a cross-sectional view of an operation in accordance with a preferred embodiment of the present invention.

### DETAILED DESCRIPTION OF THE PREFERRED EMBODIMENTS

The above and further objects and novel features of the invention will more fully appear from the following detailed description when the same is read in connection with the accompanying drawing. It is to be expressly understood, however, that the drawing is for purpose of illustration only and is not intended as a definition of the limits of the invention.

With reference to FIGS. 2 and 3 for an improved front removable expansion card module structure of the present invention, the expansion card module structure is applied in an electronic device and comprises: a casing 10, a cover panel 14 installed at the top of the casing 10, an opening 11 formed on a lateral side of the casing 10 and having a locking hole 111 formed separately on both sides of the opening 11, a fixing frame 12 fixed to the casing 10 and at a position proximate to a side of the opening 11, a first adaptor interface 13 disposed on the fixing frame 12, a first pin 131 formed at an end of the first adaptor interface 13 and erected and inserted onto a baseboard 30, and a first slot 132 formed on the first adaptor interface 13.

In addition, the opening 11 contains an adapter frame 20, a second adaptor interface 21 disposed on the adapter frame 20 and inserted into the first slot 132 of first adaptor interface 13, one or more second slots 22 formed on the second adaptor interface 21 and parallel to the opening 11, an expansion card 24 inserted into the second slot 22, a fixed plate 23 installed on the adapter frame 20 for fixing the second adaptor interface 21, and a screw 231 separately installed to both sides of the fixed plate 23 and secured into the locking hole 111 for fixing the adapter frame 20 in the casing 10. With reference to FIGS. 4 and 5, maintenance personnel simply needs to loosen the screws 231, and then pull from the adapter frame 20 from the opening 11 to separate the second adaptor interface 21 from the first slot 132, and then draw the adapter frame 20 to the outside completely for maintenance and repair, without removing the cover panel 14 from the casing 10. The present invention provides a very convenient application.

In summation of the description above, the present invention complies with the patent application requirements, and is thus duly filed for patent application. While the invention has been described with reference to a preferred embodiment thereof, it is to be understood that modifications or variations may be easily made without departing from the spirit of this invention, which is defined in the appended claims.

1. An improved front removable expansion card module structure, applicable for electronic devices, comprising:
a casing, having a cover panel installed at the top of the casing, and an opening formed on a lateral side of the casing;
a first adaptor interface, having a first pin formed at an end of the first adaptor interface and inserted into an erect baseboard, and a first slot formed on the first adaptor interface; and
an adapter frame, entered from the opening, and disposed in the casing, and having a second adaptor interface inserted into the first slot of the first adaptor interface, and one or more second slots formed on the second adaptor interface and parallel to the opening;
such that a maintenance person simply needs to pull the adapter frame from the opening to separate the second adaptor interface from the first slot, and then draw the adapter frame to the outside completely for maintenance and repair, without removing the cover panel from the casing.

2. The improved front removable expansion card module structure of claim 1, further comprising a locking hole formed separately on both sides of the opening.

3. The improved front removable expansion card module structure of claim 1, further comprising a fixing frame fixed to the casing and at a position proximate to a side of the opening, and provided for fixing the first adaptor interface.

4. The improved front removable expansion card module structure of claim 1, wherein the adapter frame has a fixed plate of a fixed second adaptor interface, and the fixed plate has a screw installed separately on both sides of the fixed plate, and the screw is secured into locking hole.

5. The improved front removable expansion card module structure of claim 1, wherein the second slot has an expansion card inserted therein.
